(19) United States
(12) Patent Application Publication
(10) Pub. No.: US 2024/0266802 A1
(43) Pub. Date: Aug. 8, 2024

(54) OPTOELECTRONIC COMPONENT AND LASER

(71) Applicant: ams-OSRAM International GmbH, Regensburg (DE)

(72) Inventors: Hubert HALBRITTER, Dietfurt (DE); Adrian Stefan AVRAMESCU, Regensburg (DE); Laura KREINER, Regensburg (DE); Bruno JENTZSCH, Regensburg (DE); Alvaro GOMEZ-IGLESIAS, Regensburg (DE)

(73) Assignee: ams-OSRAM International GmbH, Regensburg (DE)

(21) Appl. No.: 18/563,177

(22) PCT Filed: May 18, 2022
(86) PCT No.: PCT/EP2022/063415

§ 371 Date: Nov. 21, 2023

(30) Foreign Application Priority Data
May 26, 2021 (DE) 10 2021 113 598.2
Oct. 28, 2021 (DE) 102021128124.5

(51) Int. Cl. H01S 5/11; H01S 5/185; H01S 5/34; H01S 5/343

(52) U.S. Cl. CPC H01S 5/11; H01S 5/185; H01S 5/3416; H01S 5/343

(57) ABSTRACT

An optoelectronic component includes a stacked arrangement including a photonic crystal and a gain medium. The gain medium includes a layer sequence composed of two quantum wells and at least one tunnel diode and is set up to emit an electromagnetic wave. The photonic crystal is electromagnetically coupled to the gain medium. The stacked arrangement is disposed on a substrate. Alternatively or additionally, the gain medium includes at least one quantum well. The photonic crystal is structured in a dielectric layer and electromagnetically coupled to the gain medium.

### CROSS-REFERENCE TO RELATED APPLICATIONS

The present application is a national stage entry from International Application No. PCT/EP2022/063415, filed on May 18, 2022, published as International Publication No. WO 2022/248301 A1 on Dec. 1, 2022, and claims priority to German Patent Application Nos. 10 2021 113 598.2, filed May 26, 2021, and 10 2021 128 124.5, filed on Oct. 28, 2021, the disclosures of all of which are hereby incorporated by reference in their entireties.

### FIELD OF THE INVENTION

An optoelectronic component and a laser are described.

### BACKGROUND OF THE INVENTION

Due to their small size and power spectrum, semiconductor lasers are used in a wide range of applications, for example in integrated sensor solutions. Semiconductor lasers can generally be divided into two classes: Edge-emitting lasers, in which the laser light propagates parallel to the wafer surface of the semiconductor chip and is reflected or coupled out at a cleaved edge, and surface-emitting lasers, in which the light propagates perpendicular to the semiconductor wafer surface. A less common category of surface-emitting lasers is configured such that laser light propagates essentially in a cavity along the wafer surface (in-plane lasers). One realization of this type of laser is the photonic crystal surface-emitting laser (PCSEL), in which an in-plane laser resonator with a photonic crystal structure is realized. The same structure also reflects part of the light to form the output beam. Here, single-frequency operation can be achieved, which can be important for applications in 3D sensing and optical data transmission, for example.

Photonic crystal surface-emitting lasers, or PCSELs, can be realized, for example, by stacks of functional layers. In contrast to edge-emitting lasers, the lasers can and, depending on the application, should have coupled waveguides to simplify fabrication and adjust the laser characteristics for the particular application. At the same time, there is a need for high-quality components, such as the photonic crystals used.

One object is to specify an optoelectronic component and a laser that allow simpler fabrication and improved laser characteristics.

These objects are achieved by the optoelectronic component and the laser according to the independent claims. Further embodiments of the optoelectronic component and the laser are the subject of the dependent claims.

### SUMMARY OF THE INVENTION

According to one embodiment of the optoelectronic component, an optoelectronic component comprises a stack including a photonic crystal and a gain medium. The gain medium comprises a layer sequence of at least two quantum wells and at least one tunnel junction. The stack is arranged on a substrate that is transparent in the region of an electromagnetic wave to be emitted. The gain medium is configured to emit the electromagnetic wave. The photonic crystal is electromagnetically coupled to the gain medium.

To increase the luminance of lasers, especially of photonic crystal surface-emitting Lasers, PCSELs, optoelectronic components comprising stacks can be advantageous. Unlike other semiconductor lasers with multiple junctions, waveguides can and often should be coupled. This saves, for example, implementing a photonic crystal layer for each waveguide.

By coupling the waveguides, large area lasers with high power density can be generated with only diffractively limited beam collimation. Furthermore, the stacks can be arranged within a super waveguide.

With the help of the tunnel junctions, the individual quantum wells can be coherently coupled at a small spatial distance. Since in this concept only one photonic crystal layer is necessary, fabrication is additionally facilitated, since nanostructuring has to be done only after deposition of the quantum wells and the tunnel junctions and thus no additional defects are caused in the most sensitive layers of the device.

In one embodiment, an optoelectronic component comprises a stack including a photonic crystal and a gain medium. The gain medium comprises at least one quantum well and is configured to emit an electromagnetic wave. The photonic crystal is structured in a dielectric layer and is electromagnetically coupled to the gain medium. The stack is arranged on a substrate. The substrate may be transparent in the region of the electromagnetic wave, for example, to couple out the electromagnetic wave. Alternatively, the substrate may be opaque in the region of the electromagnetic wave if, for example, the electromagnetic wave is not coupled out through this side.

Due to the high collimation quality of a PCSEL, there is no significant beam widening, even when coupling-out occurs through the substrate. This means that the optical properties of the optoelectronic component used as a laser are not impaired even by “thick” substrates, for example >100 μm, and thus components can also be manufactured with much thicker substrates than previously proposed.

To realize this approach with high quality photonic crystal structures, the photonic crystal can be structured not directly into the semiconductor material, but in an additionally inserted layer close to the active zone. This layer includes dielectric material, for example in combination with another dielectric material and/or a transparent conductive material, such as indium tin oxide (ITO). Materials with good optical properties and simultaneously high thermal conductivity are particularly suitable as dielectric materials, while other dielectric materials with less good thermal properties are also suitable in principle.

One advantage of this approach over alternative concepts is that only a relatively thin layer of the semiconductor material is required. As a result, the corresponding epitaxy process takes significantly less time and thus allows a low-cost component with a comparatively simple architecture. Structuring in dielectrics can reduce or even avoid defects in the semiconductor.

In one embodiment, an optoelectronic component comprises a stack including a photonic crystal and a gain medium. The gain medium comprises at least one quantum well and is configured to emit an electromagnetic wave. The photonic crystal is structured in a conductive layer and is electromagnetically coupled to the gain medium. The stack is arranged on a substrate. The substrate may be transparent in the region of the electromagnetic wave, for example, to couple out the electromagnetic wave. Alternatively, the substrate may be opaque in the region of the electromagnetic wave if, for example, the electromagnetic wave is not coupled out through this side.

This enables, for example, photonic crystal structures on the p-side, such as in InGaN lasers. The realization within the conductive layer, which includes ITO, for example, on the p-side enables fully planarized structures that facilitate coupling-out via the p-side (AR coating)—and allows thermal coupling via the n-side, for example.

In at least one embodiment, the layer sequence comprises the at least two quantum wells and the at least one tunnel junction. Further, the photonic crystal is structured in the electric layer.

In at least one embodiment of the optoelectronic component, the photonic crystal is comprised by the gain medium such that the photonic crystal is arranged in the layer sequence.

Alternatively, the photonic crystal may be arranged separate from the gain medium such that the photonic crystal is arranged on an outer layer of the layer sequence.

In at least one embodiment, the gain medium has one or more claddings. The one or more claddings are arranged in the layer sequence such that a quantum well is spaced apart from a tunnel junction.

In at least one embodiment, a distance between the quantum well and the tunnel junction is adjusted in each case such that a fundamental mode can be coupled out of the gain medium.

In at least one embodiment, the one or more claddings are adjusted with a distance such that a distance is adjusted between the quantum well and the tunnel junction in each case such that a plurality of single modes can be coupled out of the gain medium and the single modes are coupled by energy transfer.

In at least one embodiment, the photonic crystal comprises a cladding.

In at least one embodiment, the dielectric layer comprises a first dielectric material. The dielectric layer further comprises a second dielectric material and/or a conductive material that is transparent in the region of the electromagnetic wave.

In at least one embodiment, the conductive layer comprises a first conductive material, a second conductive material, and/or a dielectric material that is transparent in the region of the electromagnetic wave.

Furthermore, the conductive layer and the dielectric layer can be combined by suitable material selection. For example, a partially dielectric and partially conductive layer can thus be provided.

In at least one embodiment, a photonic crystal structure of the photonic crystal includes the first dielectric material and is fully embedded in the second dielectric material and/or the transparent conductive material. The photonic crystal structure of the photonic crystal may at least partially not be embedded in the second dielectric material and/or the transparent conductive material on a side facing a quantum well.

In at least one embodiment, a photonic crystal structure of the photonic crystal is in direct contact with the gain medium.

In at least one embodiment, the photonic crystal is structured into a layer without conductive material.

In at least one embodiment, a laser comprises one or more of the optoelectronic components according to the concept described herein. Further, a pump source is provided and configured to excite stimulated emission by means of the gain medium.

In at least one embodiment, a method of producing an optoelectronic component comprises the following steps. First, a photonic crystal and a gain medium are arranged in a stack. The stack is further arranged on a substrate that is transparent in the region of an electromagnetic wave to be emitted. The gain medium comprises, in a layer sequence, at least two quantum wells and at least one tunnel junction. The gain medium is configured to emit the electromagnetic wave.

Finally, the photonic crystal is electromagnetically coupled to the gain medium.

In at least one embodiment, a method of producing an optoelectronic component comprises the following steps. First, a photonic crystal and a gain medium are arranged in a stack. The stack is arranged on a substrate that is transparent in the region of an electromagnetic wave to be emitted. The gain medium comprises at least one quantum well and is configured to emit the electromagnetic wave. The photonic crystal is structured in a dielectric layer and is electromagnetically coupled to the gain medium.

Further embodiments and further developments of the optoelectronic component or of the method of producing an optoelectronic component will become apparent from the exemplary embodiments explained below in connection with FIGS. 1 to 11. Identical, similar or identically acting circuit parts and components are provided with the same reference signs in the figures.

### BRIEF DESCRIPTION OF THE DRAWINGS

In the figures:

FIGS. 1 to 16 show examples of optoelectronic components.

### DETAILED DESCRIPTION

FIG. 1 shows an example of an optoelectronic component. In this example as well as in the following examples, the optoelectronic component comprises a stack, which includes a photonic crystal 1 and a gain medium 3.

The photonic crystal 1 consists, for example, of a thin layer of semiconductor material, for example gallium arsenide, GaAs, gallium nitride, GaN, or indium phosphide, InP, which is transparent to an electromagnetic wave to be emitted, i.e. not or only slightly absorbing. The electromagnetic wave to be emitted is, for example, in the infrared, IR, ultraviolet, UV, or visible, VIS, part of the electromagnetic spectrum. The photonic crystal 1 includes a photonic structure 11 that is a periodic refractive index structure and allows electromagnetic waves to be guided, filtered, and/or wavelength-selectively reflected by optical processes such as diffraction and interference. The periodic photonic structure determines or defines, for example, the emission direction, wavelength and divergence of the electromagnetic wave that can be emitted by the optoelectronic component.

The photonic crystal structure 11 comprises one- or two-dimensionally arranged structural elements 12 arranged in a pattern (for example, a square or triangular pattern) so as to form the photonic crystal structure extending over a certain direction or area. The structural elements may include air holes or dielectric material. As a two-dimensional photonic crystal structure, it functions as a lateral cavity, so to speak. For example, the photonic structure is characterized by the distance (pitch) of the structural elements from each other or their fill factors and other parameters. Not shown in the drawing is the extension of the photonic crystal in one plane, resulting in a two-dimensional distribution of the periodic photonic structure. In principle, the photonic crystal can extend along one direction, resulting in a one-dimensional distribution of the periodic photonic structure.

The gain medium 3 comprises a layer sequence of quantum wells 30, tunnel junctions 31 and claddings 32. The quantum wells are an active medium and are configured to emit the electromagnetic wave by stimulated emission when suitably excited. The gain medium is delimited by two outer claddings. In this example, the photonic crystal is a first outer cladding for the gain medium. A second outer cladding 33 delimits the gain medium from a substrate 5 on which the stack is arranged. The substrate is transparent in the region of the electromagnetic wave. The first and second outer claddings may have a different layer thickness than the claddings 32 of the gain medium. The stack of the gain medium forms a common waveguide delimited by the first and second outer claddings. In this example, the claddings 32 of the gain medium have equal layer thicknesses. For example, the layer thicknesses range from 100 nm to 500 nm. The claddings include a doped semiconductor and are n-doped or p-doped, for example.

The stack comprises several quantum wells, in this example three, but at least two quantum wells. This structure is referred to as a multi-quantum well. The first quantum well is photonically coupled to the photonic crystal. In this example, the photonic crystal is arranged on the first quantum well. The term “photonically coupled” refers to this spatial proximity which, when the optoelectronic crystal is in operation (for example, in a laser), causes an evanescent field to form between the photonic crystal and the quantum well. This will be explained in more detail below.

In the layer sequence, the first quantum well is followed by a further cladding 32, followed by a first tunnel junction 31 as well as a further cladding 32. This sequence is repeated for a second quantum well 30 with a further cladding 32, followed by a second tunnel junction 31 as well as a further cladding 32. This cladding is followed by a third quantum well 30, which in a sense concludes the stack in the direction of the substrate 5. The third quantum well 30 is arranged on the second outer cladding 33.

The tunnel junctions 31 represent pn-junctions, for example. Thus, an advantageous sequence of n- and p-doped regions can be set by the layer sequence. In this example, the sequence of the respective quantum well, cladding and tunnel junction ensures that only one fundamental mode per quantum well is established with suitable excitation. By arranging several quantum wells (multi-quantum well), a “super” fundamental mode is established by superposition, which is determined by the layer thicknesses and relative positions of the quantum wells. It has been found that layer thicknesses of less than 1 μm are advantageous for this purpose, with a layer thickness describing a sequence of the respective quantum well, cladding and tunnel junction. In this way, the quantum wells are so close to each other that the quantum wells are photonically coupled to each other and the “super” fundamental mode is established. The location of the tunnel junctions in the stack has been found to be less critical because the fundamental modes have no nodes et cetera. Thus, laser gain by stimulated emission can be achieved by coupling the photonic crystal structure to the thin active layers (quantum wells) below the photonic crystal layer within the evanescent fields corresponding to the fundamental modes.

The substrate includes two opposing surfaces. One surface 51 is provided with the outer cladding 33 so that the layer sequence is arranged on the substrate. The opposite surface 52 is optionally provided with a reflection coating 53. This reflection coating includes, for example, a (metal) reflector or a Bragg mirror. The reflection coating may also be provided on the surface 51. The reflection coating is optional because it is not a component of the resonator, or a high reflectivity on the substrate is not necessarily required for laser activity.

The optoelectronic component can be operated as part of a laser. A suitable pump source, electrical or optical, induces stimulated emission in the gain medium. For example, an electric current for pumping the active region, i.e. the quantum wells, is applied via metallic electrodes on the top and bottom surfaces of the optoelectronic component, for example on the photonic crystal and the opposite surface 52 of the substrate. The electrodes are not shown in the drawing. In this example, laser emission occurs via the top surface (indicated by an arrow) where the photonic crystal is located. For example, the electrode covers only a small portion of an emitting surface, for example a rectangular area with dimensions in the order of 10 μm to 100 μm. It is also possible to use an upper electrode with a rectangular region removed from the center. This results in pumping of the photonic crystal mode in its outer region, while output coupling is possible in the central region.

Laser gain by stimulated emission is achieved by coupling the photonic crystal structure 11 of the photonic crystal 1 with the quantum wells 30 of the gain medium as an active layer (gain layer) below the photonic crystal layer 11 within the evanescent fields of the modes. Here, the claddings adjust a distance between a quantum well and a tunnel junction in each case such that a fundamental mode can be coupled out of the gain medium. The active regions are separated from the photonic structure in the layer sequence to keep the electric charge carriers confined in the active region, but photonically coupled to it by means of the sequence of claddings 32 and tunnel junctions 31.

The optically transparent and electrically conductive cladding layer of doped semiconductor (outer cladding 33 and photonic crystal 1) is located above and below the stack. The sequence of the respective quantum well, cladding and tunnel junction thus leads to the establishment of one fundamental mode per quantum well. By arranging several quantum wells (multi-quantum well), a “super” fundamental mode is established by superposition, which is determined by layer thicknesses and relative positions of the quantum wells. By the reflection coating 53, for example Bragg reflector (Bragg mirror), on one side of the layer sequence, a more efficient power extraction can be achieved.

By coupling the waveguides, large-area lasers with high power density can be generated with only diffractively limited beam collimation. In addition, the optoelectronic components can be arranged within a super waveguide. By means of the tunnel junctions, the individual quantum wells can be coherently coupled with a small spatial distance. Since only one photonic crystal layer is required in this concept, fabrication is additionally facilitated since nanostructuring can be performed only after deposition of the quantum wells and the tunnel junctions, thus avoiding additional defects in the most sensitive layers of the device.

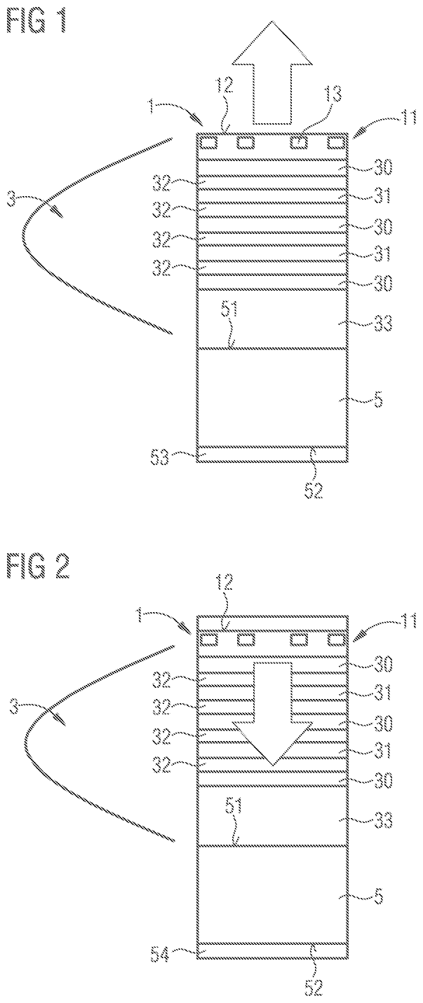

FIG. 2 shows another example of an optoelectronic component. The optoelectronic component is based on the previous example and has been modified only in the following features compared to FIG. 1.

The reflection coating 53 is now arranged on an outer surface 12 of the photonic crystal. This reflection coating includes, for example, a (metal) reflector or a Bragg mirror and is optional because it is not a component of the resonator, or a high reflectivity is not necessarily required for laser activity. An anti-reflection coating 54 may be applied to the surface 52 of the substrate to assist in coupling out laser light in the direction of the substrate 5. In this example, laser emission occurs along the bottom surface of the component (indicated by an arrow), i.e. in the direction of the substrate 5.

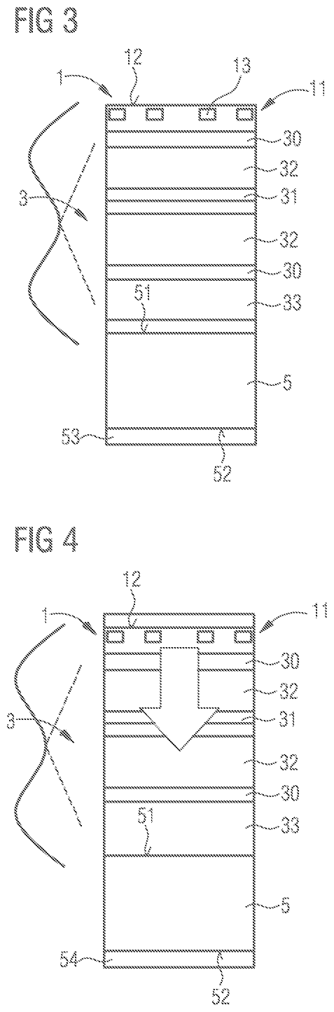

FIG. 3 shows a further example of an optoelectronic component. The optoelectronic component is also a further development of the example in FIG. 1 and has been modified only in the following features.

The gain medium 3 comprises a different layer sequence than described in FIG. 1. In the layer sequence, a first quantum well is first followed by a cladding 32, followed by a tunnel junction 31. This is followed by a further cladding 32. This cladding is followed by a second quantum well 30, which in a sense concludes the layer sequence in the direction of the substrate 5. In this example, no third quantum well is provided. Instead, the second quantum well is terminated by an outer cladding 33. The photonic crystal 1 represents another outer cladding.

In contrast to FIG. 1, the claddings 32 each have a different layer thickness than the tunnel junction 31 or the quantum wells 30. The layer thickness of the claddings 32 is selected so that a distance between a quantum well and the tunnel junction is adjusted such that several single modes can be coupled out of the gain medium. Due to the selected distance, the single modes are coupled by energy transfer.

Laser gain by stimulated emission is achieved by coupling the photonic crystal structure 11 of the photonic crystal 1 with the quantum wells 30 of the gain medium as an active layer (gain layer) below the photonic crystal layer 11 within the evanescent fields of the modes. Here, the claddings adjust a distance between a quantum well and the tunnel junction in each case such that the gain medium is divided into two waveguides, each forming a single mode. The active regions are separated from the photonic structure in the layer sequence to keep the electric charge carriers confined in the active region, but photonically coupled to the same by means of the sequence of claddings 32 and the tunnel junction 31. Above and below the layer sequence is the optically transparent and electrically conductive cladding layer of doped semiconductor (outer cladding 33 and photonic crystal 1).

The sequence of quantum well, cladding and tunnel junction thus results in one single mode per quantum well or waveguide. By choosing the layer thicknesses of the quantum wells (multi-quantum well), tunnel junction and claddings, it can be achieved that the waveguides are coherently coupled. The establishing single modes overlap and exchange energy by coupling. This allows laser light to be coupled out of a central photonic crystal.

FIG. 4 shows another example of an optoelectronic component. The optoelectronic component is based on the previous example and has only been modified in the following features compared to FIG. 3.

The reflection coating 53 is now arranged on an outer surface 12 of the photonic crystal. This reflection coating includes, for example, a (metal) reflector or a Bragg mirror and is optional because it is not a component of the resonator, or a high reflectivity is not necessarily required for laser activity. An anti-reflection coating 54 may be applied to the surface 52 of the substrate to assist in coupling out laser light in the direction of the substrate 5. In this example, laser emission occurs along the bottom surface of the component (indicated by an arrow) in the direction of the substrate 5.

FIG. 5 shows another example of an optoelectronic component. In this example, the photonic crystal is arranged in the layer sequence.

In further embodiments, the photonic crystal may also be located between the waveguides, for example within the tunnel junction or in an intermediate cladding 32. Thin, low-loss tunnel junctions may be advantageous. The photonic crystal structures can also be located on the substrate side. The structure of the photonic crystal (pitch, fill factor, etc.) determines or defines the emission direction, wavelength and divergence.

Due to the high collimation quality of a PCSEL, there is no significant beam widening, even when coupling-out occurs through the substrate. This means that the optoelectronic component itself is not significantly affected in its optical properties by a somewhat “thick” substrate (for example >100 μm) and thus components with much thicker substrates than previously proposed can be fabricated. To realize this approach with high quality photonic crystal structures, the photonic crystal can be structured into a dielectric layer instead of directly into a semiconductor material. This additionally inserted layer can be located close to the active region, i.e. the quantum wells, of the gain medium. This sort of structuring in dielectrics can avoid defects in the semiconductor.

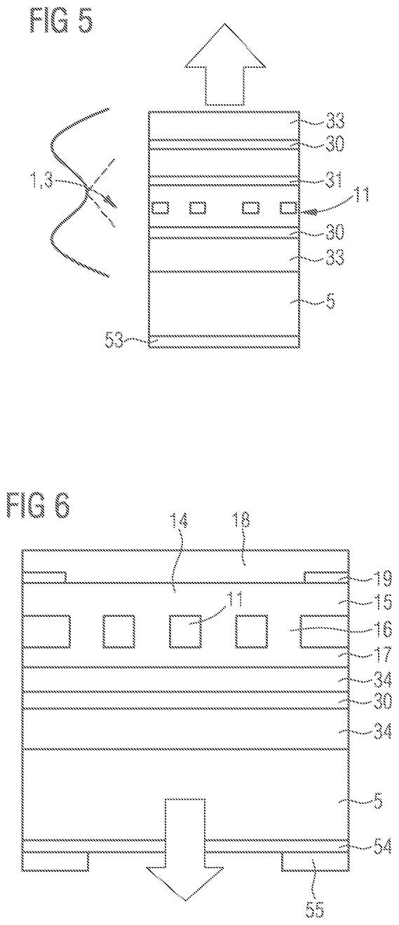

FIG. 6 shows another example of an optoelectronic component. The optoelectronic component comprises a stack including a photonic crystal 1 and a gain medium 3. The gain medium comprises a quantum well 30 which, as an active medium, is configured to emit an electromagnetic wave.

The gain medium is arranged on a transparent substrate 5. The substrate includes a semiconductor material, for example gallium arsenide, GaAs, gallium nitride, GaN, or indium phosphide, InP, which is transparent for the electromagnetic wave to be emitted, i.e. not or only slightly absorbing. The electromagnetic wave to be emitted lies, for example, in the infrared, IR, ultraviolet, UV, or visible, VIS, part of the electromagnetic spectrum.

An anti-reflection coating 54 is applied to a surface 52 of the substrate to assist in coupling out laser light in the direction of the substrate 5. Furthermore, an electrode 53, for example an n-contact, is disposed on the surface 52. In this example, laser emission occurs along the bottom surface (indicated by an arrow). The electrode is configured to cover only a small portion of the surface 53, for example a rectangular area with dimensions in the order of 10 μm to 100 μm. It is also possible to use an electrode with a rectangular region removed from the center. This results in pumping of the photonic crystal mode in its outer region, while output coupling is possible in the central region.

On another surface 51 of the substrate opposite the surface 52, the gain medium is arranged with a layer sequence. The layer sequence comprises differently doped semiconductors enclosing a quantum well 30. In this example, a first semiconductor layer 34 of n-doped GaN is arranged on the surface 51, followed by a quantum well 30. A second semiconductor layer 34 of p-doped GaN is in turn arranged on the quantum well.

The embodiment of the gain medium, in particular the layer sequence, can be replaced or extended by one from FIGS. 1 to 5, wherein the semiconductor layers 34 can be replaced or supplemented by claddings. In this way, the embodiments of FIGS. 1 to 5 can be replaced or supplemented with those of FIGS. 6 to 10.

The photonic crystal 1 is structured in a dielectric layer 14 and is electromagnetically coupled to the gain medium. In this regard, the dielectric layer 14 comprises a first layer 15 comprising a first dielectric material, in this example ITO. The photonic structure 11 is structured into a second layer 16, which also includes the first dielectric material. The structural elements 13 include a second dielectric material. The dielectric layer 14 further comprises a third layer 17, which makes contact with the gain medium.

The dielectric layer 14 includes dielectric material in combination with another dielectric material and/or a transparent conductive material, such as indium tin oxide (ITO for short). Materials with good optical properties and simultaneously high thermal conductivity are particularly suitable as dielectric materials, while other dielectric materials with less good thermal properties are also suitable in principle, but may have other disadvantages. ITO can be mixed with TCO, where TCO refers to transparent, electrically conductive oxides. Suitable materials are, for example:

| | |
|---|---|
| ITO/CaF | n_TCO > n_dielectric |
| ITO/SiO | n_TCO > n_dielectric |
| ITO/MgF | n_TCO > n_dielectric |
| ITO/TiO | n_TCO < n_dielectric |
| ITO/TaO | n_TCO < n_dielectric |

For example, the refractive indices given below can be used.

Further, a second electrode 18, for example a p-contact, is arranged on the photonic crystal. The electrode comprises for example a material reflective for the electromagnetic radiation to be emitted (for example Au or Al). Optionally, the electrode may be comprised by an insulator configured in the form of an aperture 19 to provide a current aperture.

By means of the two electrodes, the optoelectronic component can be excited to stimulated emission and emission of the electromagnetic wave as laser radiation. In the structure proposed here, the photonic structure made of a dielectric material is completely embedded in a transparent conductive material to form the photonic crystal. The layer thicknesses of p-GaN and the directly adjacent closed ITO layer are preferably very thin to ensure a small distance (<300 nm, preferably <100 nm to ˜50 nm) of the photonic crystal from the quantum wells. An advantage of this approach compared to alternative concepts is that only a relatively thin layer of the semiconductor material is required in the gain medium. As a result, the corresponding epitaxial process takes significantly less time, thus allowing a low-cost component having a comparatively simple architecture.

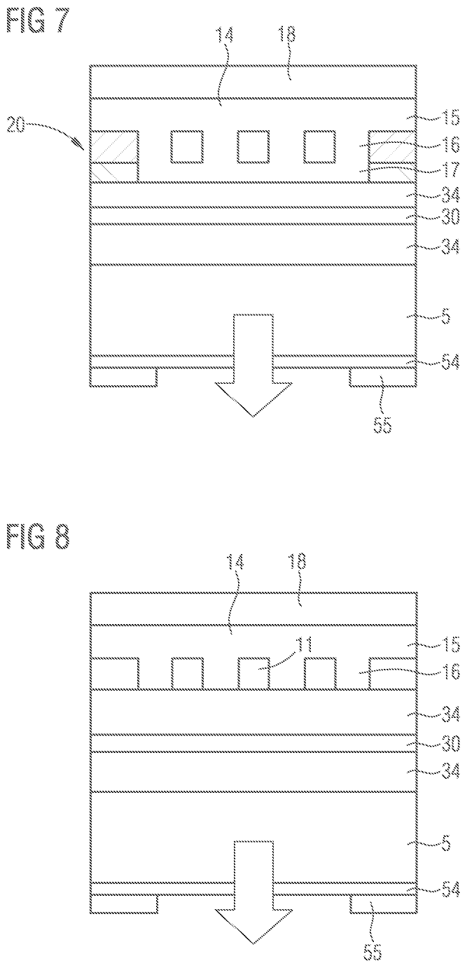

FIG. 7 shows another example of an optoelectronic component. The optoelectronic component corresponds to the example in FIG. 6, but this embodiment has an aperture 20 in addition to the photonic structure. The aperture can be made directly of the same material system as the photonic crystal and/or of another material such as metal. For example, the aperture delimits the dielectric layer (for example, layers 16, 17). The aperture can be used to advantageously influence laser characteristics such as beam widening or divergence.

FIG. 8 shows another example of an optoelectronic component. The optoelectronic component corresponds to the example in FIG. 6 with the difference that the dielectric layer 14 comprises only the first and second layers 15, 16 and no third layer 17. Instead, the contact to the gain medium is established directly by means of the second layer 16. In this setup, the distance between the photonic structure and the quantum wells is thus further reduced by not providing a closed dielectric layer, for example ITO layer, between p-GaN and photonic crystal. Here, it is important that good charge transport to the active zone can still occur. Also in this case, an aperture 19 can be structured on or into the photonic crystal.

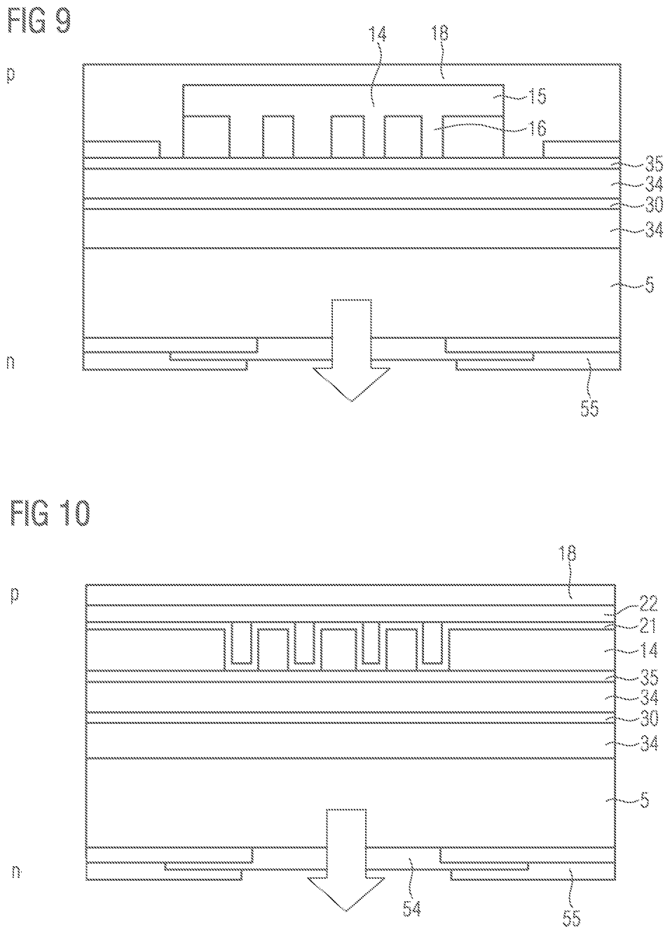

FIG. 9 shows another example of an optoelectronic component. The optoelectronic component is a further development of FIG. 8 with the difference that the photonic crystal is structured into a dielectric layer 14 which does not include conductive material. For example, the dielectric layer includes two dielectric materials having different refractive indices. To nevertheless ensure good contacting, an intermediate layer 35 is inserted in the layer sequence with very good transverse conductivity (for example, p++ GaN) between the photonic crystal 1 and the gain medium 3.

Further, a second electrode 18, for example a p-contact, is arranged on the photonic crystal. The dielectric layer 14 is embedded in the electrode. The electrode comprises a material reflective to the electromagnetic radiation to be emitted (for example, Au or Al). Optionally, the electrode may be comprised by an insulator configured in the form of a (current) aperture 19 to provide a current aperture. Furthermore, the substrate 5 may also have a (current) aperture 19 on the surface 52 as well as an electrode 55, for example an n-contact, and an anti-reflection coating 54.

FIG. 10 shows another example of an optoelectronic component. The optoelectronic component is a further development of the exemplary embodiment of FIG. 9. In this setup the photonic crystal is structured by a combination of conductive material (for example TCO) and dielectrics, for example the conductive material consists of two different TCO materials or the TCO is deposited by two different methods. First, a TCO1 film 21 is deposited by means of, for example, ALD, said TCO1 film 21 being deposited into the depths of the photonic crystal where it makes contact with GaN p++. In the next step, a planar TCO2 film 22 is deposited, which planarly seals the photonic crystals but does not fill them up. The p-contact is thus realized via TCO2 and TCO1 to p-GaN.

As a result, the dielectric layer 14 includes the first layer 15 in which the structural elements 13 are embedded. The layer 15 and the structural elements are covered with the film 21. The film 22 forms a planar seal on the film 21.

The optoelectronic component can be developed further. For example, the photonic crystal structure is processed by means of a molding of a shape-retaining layer, such as silicon. The silicon is structured in the process. Subsequently, the dielectric is deposited—it forms a mold of the silicon. Afterwards, the silicon is removed again (however, depending on the wavelength/absorption of Si at the wavelength, the silicon may remain). The further process can be done as described in FIG. 10. In general, instead of a dielectric, for example a-Si with a high refractive index can be used. Because of the thin layer, the absorption in Si—even at e.g. 450 nm is acceptable (e.g. 80% transmission at 100 nm thickness at 450 nm). However, since the Si occupies only a part of the photonic crystal, the transmission is much higher (fill factor). a-Si has the advantage over other dielectrics that it can be structured very precisely, for example.

The concept presented here is suitable for GaN-based PC-VCSELs, but can also be used for GaAs- and InP-based systems. Especially since the advantages become quite clear here. In principle, a mirror can also be used on the substrate side. The exemplary embodiments can also be configured for coupling out laser emission via the top surface, with the metallization being adapted for this purpose, for example.

| | |
|---|---|
| SiO | n = 1.465 |
| SiN | n = 2.055 |
| TaO | n ~ 2.16 |
| TiO | n ~ 2.8 |
| NbO | n ~ 2.445 |
| HfO | n ~ 1.91 |
| CaF | n = 1.438 |
| MgF2 | n = 1.38 |
| AlO | n ~ 1.77 |
| AlN | n ~ 2.2 |
| ITO | n ~ 1.9 (depending on TCO material) |
| GaN | n ~ 2.46 |

The term ITO is used here to represent various TCO (transparent conductive oxide) materials, ITO being one of them.

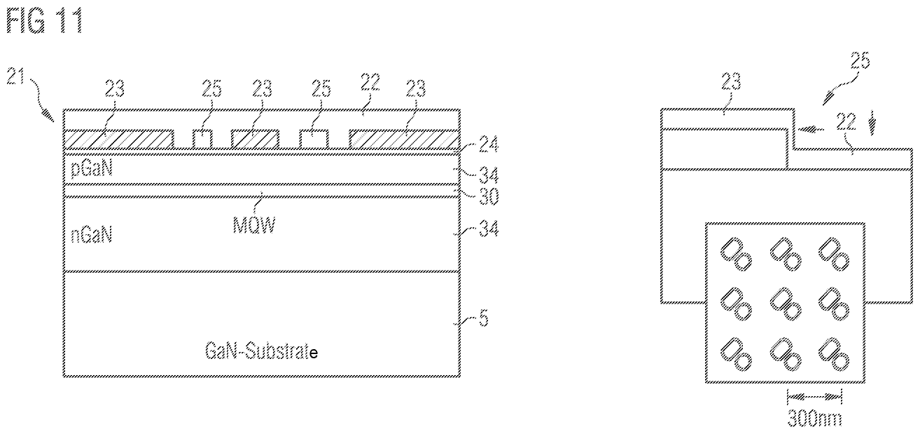

FIG. 11 shows another example of an optoelectronic component. The optoelectronic component comprises a stack including a photonic crystal and a gain medium. The gain medium comprises a quantum well 30, which is an active medium configured to emit an electromagnetic wave.

The gain medium is arranged on a transparent substrate 5. The substrate includes a semiconductor material, for example gallium arsenide, GaAs, gallium nitride, GaN, or indium phosphide, InP, which is transparent to the electromagnetic wave to be emitted, i.e. not or only slightly absorbing. The electromagnetic wave to be emitted is, for example, in the infrared, IR, ultraviolet, UV, or visible, VIS, part of the electromagnetic spectrum. The gain medium includes two semiconductor layers 34. For example, a first semiconductor layer is p-doped and a second semiconductor layer is n-doped. In this example, the second semiconductor layer faces the gain medium and is n-doped (for example, nGaN) and the first semiconductor layer faces a conductive layer 21 and is p-doped (for example, pGaN).

The design of the gain medium of this and the following embodiments, in particular the layer sequence, can be replaced or extended by one from FIGS. 1 to 10, wherein the semiconductor layers 34 can be replaced or supplemented, for example, by claddings. In this way, the exemplary embodiments shown can be replaced or supplemented.

A photonic crystal is structured in the conductive layer 21 and is electromagnetically coupled to the gain medium. In this regard, the conductive layer 21 comprises a first layer 22 which includes a first conductive material. This may be a TCO, where “TCO” refers to transparent electrically conductive oxides. In this example, the first conductive material is ITO. The first layer 22 is used for laterally sealing the optoelectronic component. A photonic structure is structured into a second layer 23, which also includes the first conductive material. The photonic structure is formed by structural elements 25 (voids). The structural elements are shown in magnification on the right illustration and are, for example, in the order of magnitude of the emission wavelength of the optoelectronic component, for example around 300 nm. The structuring of the second layer 23 and thus of the structural elements 25 is carried out, for example, by an edging process. The conductive layer 21 further comprises a third layer 24, which makes contact with the gain medium 3. In this example, the third conductive layer 24 is arranged in a planar fashion on a surface of the gain medium.

The conductive layer 21 or the layers 22, 23, 24, respectively, can be produced by different deposition methods, for example atomic layer deposition (ALD), sputtering methods or settings. A variant with overgrown or oversputtered voids 25 has the additional advantage that the etched structures can originally be larger than they are needed in the end (since they become partially overgrown during sputtering). This provides more freedom or further options regarding the structuring processes and resolution. In particular, an anti-reflection coating (AR) can be applied to closed structures.

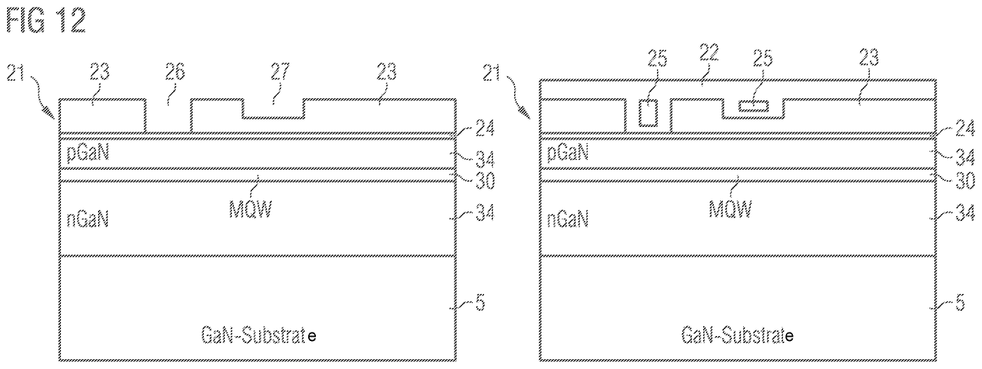

FIG. 12 shows another example of an optoelectronic component. The optoelectronic component, in particular the conductive layer 21 from FIG. 11, can be structured by etching and masking. Structural elements 25 of different depths can be produced in this process.

The left drawing shows a structuring that can be achieved by a combination of two lithography steps, each followed by an etching step. Alternatively, one gray lithography step and one etching step can be performed, which allows good alignment between sublattices. By either alternative, structures 26, 27 of different depths can be introduced into the second layer 23. These structures can then be formed by depositing the second layer 23 alone and/or together with the first layer 22, forming the structural elements 25. The right drawing shows the subsequently formed structural elements. The conductive material, for example ITO, can be applied by sputtering and encapsulate the structures 26, 27.

Furthermore, the first layer 22 can also be applied in this step and finally planarized.

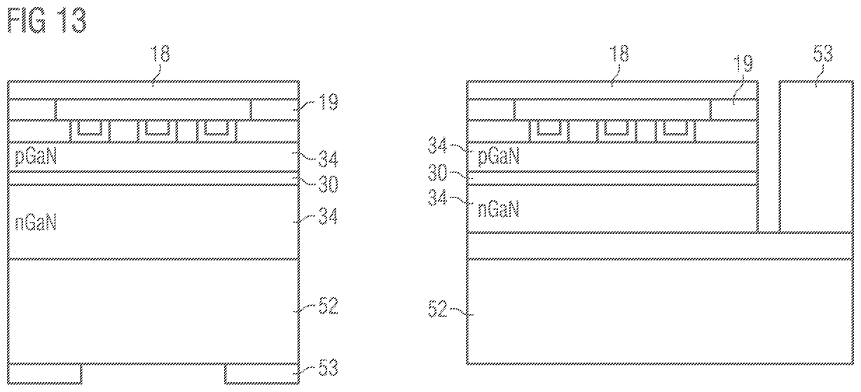

FIG. 13 shows further examples of an optoelectronic component. The drawing on the left shows the optoelectronic component according to FIG. 11, with an electrical contact being additionally shown. An electrode 53, for example an n-contact, is arranged on a surface 52 of the substrate. Optionally, an anti-reflection coating can be applied to the surface 52 to assist in coupling out laser light.

In this example, laser emission occurs along the bottom surface 52. The electrode is configured to cover only a small portion of the surface 52, for example a rectangular area with dimensions on the order of 10 μm to 100 μm. It is also possible to use an electrode with a rectangular region removed from the center. This results in pumping of the photonic crystal mode in its outer region, while output coupling is possible in the central region.

Further, a second electrode 18, for example a p-contact, is arranged on the photonic crystal. The electrode comprises, for example, a material reflective for the electromagnetic radiation to be emitted (for example Au or Al). The second electrode 18 allows contacting from the rear side. Optionally, the first or second electrode may be comprised by an insulator configured in the form of an aperture 19 to provide a current aperture.

An alternative arrangement of the second electrode 18 is shown on the right side of the drawing. Instead of on the surface 52 of the substrate, the electrode is arranged in the semiconductor layer 34 and next to the gain medium, for example in the second, n-doped semiconductor layer facing the gain medium. The second electrode 18 thus allows contacting from the front side.

By means of the two electrodes, the optoelectronic component can be excited to stimulated emission and emission of the electromagnetic wave as laser radiation. In the setup proposed here, the photonic structure made of a conductive material is completely embedded in a transparent conductive material, thus forming the photonic crystal. The electrodes are configured such that emission occurs on the substrate side by means of the aperture 19 of the first electrode.

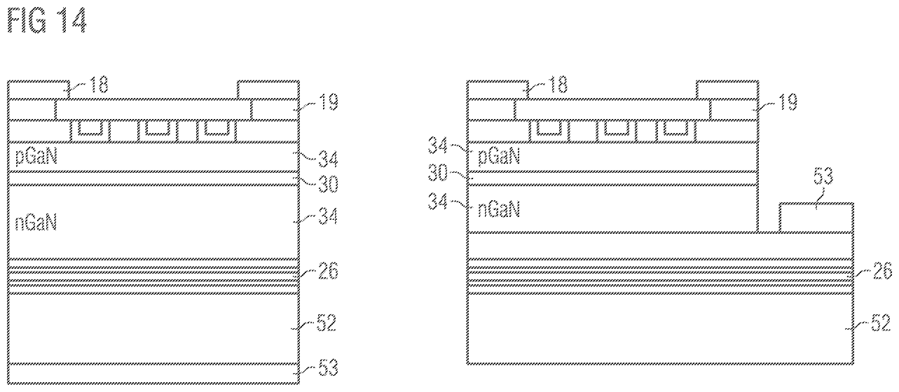

FIG. 14 shows further examples of an optoelectronic component. The drawing on the left shows the optoelectronic component according to FIG. 12 (left), with a reflector 26, in particular an epi-DBR reflector, being additionally arranged on or in the substrate. The electrodes are configured such that emission occurs on the top side by means of the aperture 19 of the first electrode.

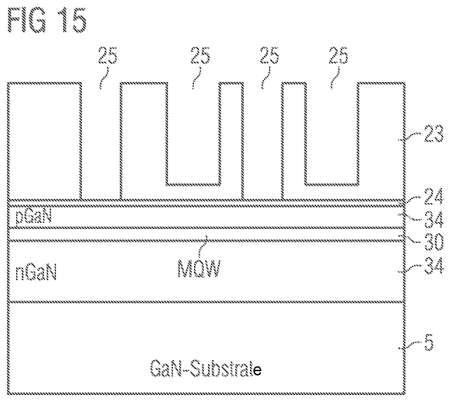

FIG. 15 shows another example of an optoelectronic component. This component corresponds to the one shown in FIG. 11, but the conductive layer 21 is open, i.e. no first layer 21 is provided for laterally sealing the optoelectronic component. The structures 26, 27 remain without encapsulation and thus form the structural elements of the optoelectronic component. A current distribution can be formed laterally in the conductive layer 21, for example in intermediate ridges of the ITO.

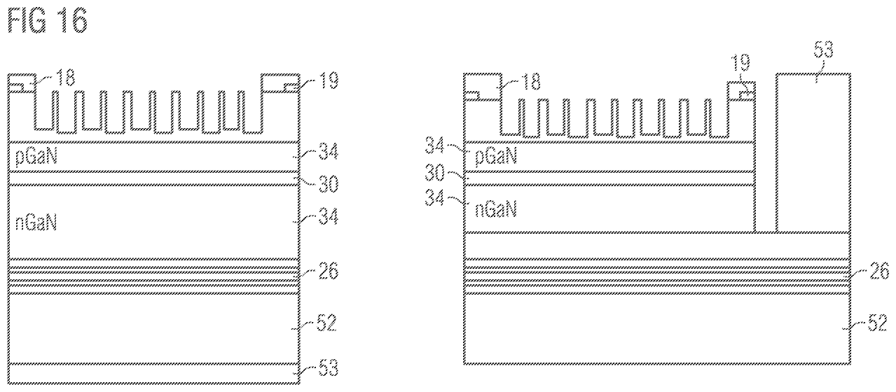

FIG. 16 shows further examples of an optoelectronic component. These components correspond to the ones shown in FIG. 15, with a reflector, in particular an epi-DBR reflector, being additionally arranged on or in the substrate.

The invention is not limited to the exemplary embodiments by the description based on the same. Rather, the invention encompasses any new feature as well as any combination of features, which in particular includes any combination of features in the patent claims, even if this feature or combination itself is not explicitly stated in the claims or exemplary embodiments.

1. An optoelectronic component comprising a stack including exactly one photonic crystal and a gain medium, wherein:
the gain medium comprises a layer sequence of at least two quantum wells and at least one tunnel junction and is configured to emit an electromagnetic wave,
the photonic crystal is electromagnetically coupled to the gain medium, and
the stack is arranged on a substrate.

2. An optoelectronic component comprising a stack including a photonic crystal and a gain medium, wherein:
the gain medium comprises at least one quantum well and is configured to emit an electromagnetic wave,
the photonic crystal is structured in a dielectric layer and is electromagnetically coupled to the gain medium, and
the stack is arranged on a substrate.

3. An optoelectronic component comprising a stack including exactly one photonic crystal and a gain medium, wherein:
the gain medium comprises at least one quantum well and is configured to emit an electromagnetic wave,
the photonic crystal is structured in a conductive layer and is electromagnetically coupled to the gain medium, and
the stack is arranged on a substrate.

4. The optoelectronic component according to claim 1, wherein:
the layer sequence comprises the at least two quantum wells and the at least one tunnel junction, and
the photonic crystal is structured in the dielectric layer.

5. The optoelectronic component according to claim 3,
wherein the photonic crystal is comprised by the gain medium such that the photonic crystal is arranged in the layer sequence.

6. The optoelectronic component according to claim 3,
wherein the photonic crystal is arranged separate from the gain medium such that the photonic crystal is arranged on an outer layer of the layer sequence.

7. The optoelectronic component according to claim 3, wherein:
the gain medium has one or more claddings, and
the one or more claddings are arranged in the layer sequence such that a quantum well is spaced apart from a tunnel junction.

8. The optoelectronic component according to claim 7,
wherein the one or more claddings adjust a distance between the quantum well and the tunnel junction in each case such that a fundamental mode can be coupled out of the gain medium.

9. The optoelectronic component according to claim 7,
wherein the one or more claddings adjust a distance between the quantum well and the tunnel junction in each case such that a plurality of single modes can be coupled out of the gain medium and the single modes are coupled by energy transfer.

10. The optoelectronic component according to claim 7,
wherein the photonic crystal comprises a cladding.

11. The optoelectronic component according to claim 3, wherein the dielectric layer comprises:
a first dielectric material,
a second dielectric material and/or a conductive material transparent in the region of the electromagnetic wave, and/or wherein the conductive layer comprises:
a first conductive material,
a second conductive material and/or a dielectric material transparent in the region of the electromagnetic wave.

12. The optoelectronic component according to claim 11,
wherein a photonic crystal structure of the photonic crystal comprises the first dielectric material and is fully embedded in the second dielectric material and/or the transparent conductive material.

13. The optoelectronic component according to claim 12, wherein:
the photonic crystal structure of the photonic crystal is at least partially not embedded in the second dielectric material and/or the transparent conductive material on a side facing a quantum well.

14. The optoelectronic component according to claim 12,
wherein a photonic crystal structure of the photonic crystal is in direct contact with the gain medium.

15. The optoelectronic component according to claim 3,
wherein the photonic crystal is structured into a layer without conductive material.

16. A laser comprising:
one or more of the optoelectronic components according to claim 3, and
a pump source configured to excite stimulated emission by means of the gain medium.
